(19) United States
(12) Patent Application Publication
(10) Pub. No.: US 2025/0072131 A1
(43) Pub. Date: Feb. 27, 2025

(54) LIGHT SENSOR

(71) Applicant: STMICROELECTRONICS INTERNATIONAL N.V., Geneva (CH)

(72) Inventor: Jean SCHOLLHAMMER, Grenoble (FR)

(21) Appl. No.: 18/799,430

(22) Filed: Aug. 9, 2024

(30) Foreign Application Priority Data
Aug. 25, 2023 (FR) 2308947

(51) Int. Cl. H01L 27/146

(52) U.S. Cl. CPC H01L 27/14685; H01L 27/14627

(57) ABSTRACT

The present disclosure relates to a method of manufacturing a light sensor comprising a matrix of pixels each associated to a micro-lens having a shift with respect to the pixel. For each axis of a plurality of axes passing by the optical center of the matric, for each pixel on the axis, and for each of a plurality light incident angles, a response value of the pixel is obtained. Based on the response values, for each axis and each pixel on the axis, a first function providing the light incident angle for which the pixel has the best response value is determined. For each axis and each pixel on the axis, a second value of the shift for bringing closer the first function to a target function is determined. The sensor is manufactured using the second values of shift.

### CROSS REFERENCE TO RELATED APPLICATIONS

This application claims the priority benefit of French Patent Application No. 23/08947 filed on Aug. 25, 2023, entitled “Capteur de lumière”, which is hereby incorporated by reference to the maximum extent allowable by law.

### TECHNICAL FIELD

The present disclosure relates generally to electronic circuits, and, more particularly, to light sensors, for example image sensors.

### BACKGROUND

Known light sensors each comprises a matrix of pixels, the pixels being arranged in columns and rows of pixels. Further, each of these known light sensors comprises a matrix of micro-lenses such that each pixel of the sensor is associated with a corresponding micro-lens of the matrix of micro-lenses. For each pixel, the micro-lens associated to the pixel, or, said otherwise, the associated micro-lens is arranged on the pixel.

Such known light sensors are configured to be mounted with a lens module, the lens module being arranged above the matrix of micro-lenses, which is itself arranged above the matrix of pixels. The lens module is configured to focus the incident light on the matrix of micro-lenses, each micro-lens then focusing the incident light in its associated pixel.

Depending on the angle made by the incident light with the optical axis of the sensor, the lens module focuses the incident light at different points on the matrix of micro-lenses with different angles of incident light on the micro-lenses. The optical axis of the sensor, for example, corresponds to the optical axis of the lens module. Said otherwise, the optical axis of the sensor is, for example, an axis perpendicular to the matrix of pixels and passing by the optical center of the matrix. The angle the focused light made with the optical axis, for example, corresponds to the angle made between the chief ray of the focused light and the optical axis of the sensor or, said otherwise, corresponds to the chief ray angle (CRA). This angle between the chief ray of the focused light and the optical axis of the sensor corresponds to the angle between the chief ray of the incident light on the micro-lenses and the optical axis of the sensor.

The variations of the angle of the incident light on the lens module result in corresponding variations of the chief ray angle of the light incident on the micro-lenses. The variations of the chief ray angle induce shading in the image generated by the light sensor.

In order to compensate the shading effect, it is known to apply, for each pixel, a shift between the associated micro-lens and the pixel along an axis passing by the optical center of the matrix of pixels and the pixel, preferably the center of the pixel. In known sensors, for each pixel, the value of the shift is only determined by the distance between the pixel and the optical center of the matrix of pixels. Said otherwise, all the pixels arranged on a same circle centered on the optical center of the matrix have each an identical value of shift between the pixel and its associated micro-lens along the radius passing by the pixel. This known manner of shifting the micro-lenses with respect to the pixels in a sensor is, for example, named “circular shift”.

However, with the reduction of the size of the pixels and/or with the change in the shape of the pixels which become asymmetric, the circular shift is no longer efficient for compensating the shading.

### BRIEF SUMMARY

There is a need to overcome at least part of the drawbacks of known light sensor.

For example, there is a need for a sensor in which the compensation of the shading effect is improved with respect to known light sensors having a circular shift between the micro-lenses and the pixels of the sensors.

One embodiment addresses all or some of the drawbacks of known light sensors.

For example, one embodiment improves the compensation of the shading effect with respect to known light sensors having a circular shift between the micro-lenses and the pixels of the sensors.

For example, one embodiment improves the compensation of the shading effect by taking into consideration the shape of the pixels.

One embodiment provides a method of manufacturing a light sensor comprising a matrix of pixels each associated to a micro-lens having a shift with respect to the pixel, along an axis passing by the optical center of the matrix and the pixel, the method comprising the following steps:
1) in a case where, for each pixel, a first value of the shift is only determined by a distance of the pixel from the optical center of the matrix, obtaining by simulation or measurement, for each axis of a plurality of axes passing by the optical center of the matrix, for each pixel on said axis, and for each of a plurality of values of light incident angle on the matrix, a response value of the pixel for a chosen figure of merit;
2) from said response values, for each axis of the plurality of axes, determining a first function providing, for each distance between the optical center of the matrix and a pixel on said axis, the value of the light incident angle for which the pixel has the best response value;
3) for each axis of the plurality of axes, for each pixel on said axis, determining a second value of the shift for bringing closer the first function to a second function providing, for each distance between the optical center of the matrix and a pixel on said axis, a target value of the light incident angle for which the pixel has the best target response;
4) manufacturing the sensor with, for each axis of the plurality of axes, and for each pixel on said axis, the value of the shift between the pixel and the associated micro-lens along the axis equal to the second value of the shift determined for the pixel.

According to one embodiment, the figure of merit is chosen in the group comprising the quantum efficiency of the pixel, the relative illumination of the pixels, a modulation transfer function of the pixel and the parasitic light sensitivity of the pixel and, for example, figures of merit of the pixel each being dependent of the angle of incidence of the light on the pixel.

According to one embodiment, an orientation of each of at least two axes among the plurality of axes is determined by a shape of the pixels and an orientation of the pixels in the matrix.

According to one embodiment, step 4) comprises, for each axis of the plurality of axes and for each pixel on the axis:
selecting the value of the light incidence angle for which said pixel verifies the second function;
determining the distance from the optical center for which another pixel on said axis verifies the first function for the value of the light incidence angle selected, the second value of shift determined for said pixel being equal to the first value of shift of said another pixel.

According to one embodiment, the step 3) further comprises interpolating a plurality of isometric lines of the second values of shift, the isometric lines being concentric with the optical center and each isometric line passing by each pixel of each axis of the plurality of axes having its second value of shift equal to the second value of shift of said isometric line.

According to one embodiment, in step 4), when manufacturing the sensor, for each pixel, the value of the shift between the pixel and the associated micro-lens along an axis passing by the optical center of the matrix and by said pixel is determined by, for example is equal to, the second value of shift of the isometric line passing by said pixel.

According to one embodiment, the plurality of axes comprises exactly two axes perpendicular to each other.

According to one embodiment, the plurality of axes comprises exactly two axes perpendicular to each other, and the isometric lines each has an elliptical shape.

According to one embodiment, the sensor is configured to be assembled with a lens module, and, at step 3), the second function is determined by the chief ray angle function of the lens module.

Another embodiment provides a light sensor comprising a matrix of pixels each associated to a micro-lens having a shift with respect to the center of the pixel along an axis passing by the optical center of the matrix and by the pixel, wherein, for each of a plurality of axes passing by the center of the matrix, the value of the shift along this axis between a pixel disposed on said axis and its associated micro-lens is determined by the distance of the pixel from the optical center of the matrix and is different, for a same distance, between at least two axes of the plurality of axes.

According to one embodiment, an orientation of each of at least two axes among the plurality of axes is determined by a shape and an orientation of the pixels.

According to one embodiment:
a plurality of isometric lines of the values of the shift are defined so that the isometric lines are concentric with the optical center and each isometric line passes by each pixel of each axis of the plurality of axes having a value of the shift between said pixel and its associated micro-lens which is equal to the value of shift of said isometric line; and the value of the shift between each pixel and its associated micro-lens along an axis passing by the optical center of the matrix and by said pixel is determined by, for example is equal to, the value of shift of the isometric line passing by said pixel.

According to one embodiment, the plurality of axes comprises exactly two axes.

According to one embodiment, the plurality of axes comprises exactly two axes and each isometric line has an elliptical shape.

### BRIEF DESCRIPTION OF DRAWINGS

The foregoing features and advantages, as well as others, will be described in detail in the following description of specific embodiments given by way of illustration and not limitation with reference to the accompanying drawings, in which:

FIG. 1 illustrates, in a schematic manner, an example of a light sensor having a circular shift between its micro-lenses and its pixels;

FIG. 2 illustrates, by a flow chart, an embodiment of a method for manufacturing a light sensor;

FIG. 3 illustrates an embodiment of a step of the method of FIG. 2;

FIG. 4 illustrates an embodiment of other steps of the method of FIG. 2;

FIG. 5 illustrates an example embodiment of a sensor manufactured using the method of FIG. 2;

FIG. 6 illustrates another example embodiment of a sensor manufactured using the method of FIG. 2; and

FIG. 7 illustrates, by a curve, the chief ray angle function, or CRA function, of an example of a lens module.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the operations and elements that are useful for an understanding of the embodiments described herein have been illustrated and described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless indicated otherwise, when reference is made to absolute positional qualifiers, such as the terms “front”, “back”, “top”, “bottom”, “left”, “right”, etc., or to relative positional qualifiers, such as the terms “above”, “below”, “higher”, “lower”, etc., or to qualifiers of orientation, such as “horizontal”, “vertical”, etc., reference is made to the orientation shown in the figures.

Unless specified otherwise, the expressions “around”, “approximately”, “substantially” and “in the order of” signify within 10%, and preferably within 5%.

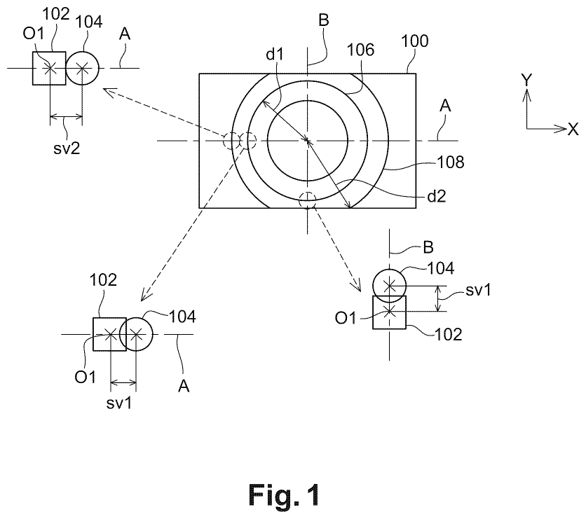

FIG. 1 illustrates, in a schematic manner, an example of a light sensor having a circular shift between its micro-lenses and its pixels. FIG. 1 is more particularly a top view of a matrix 100 of pixels 102 of a light sensor. The pixels 102 are not represented in the matrix 100, only few pixels 102 and their associated micro-lenses 104 being represented in FIG. 1, outside of the matrix 100 and with a larger scale. In FIG. 1, each represented pixel 102 corresponds to a square, and each represented micro-lens corresponds to a circle.

The column of pixels 102 of the matrix 100 are parallel to a direction X, and the rows of pixels 102 of the matrix 100 are parallel to a direction Y, the direction Y being orthogonal to the direction X.

In this example, the shift between the micro-lenses 104 and the pixels 102 of the sensor is a circular shift.

Thus, all the pixels 102 which are arranged at a same distance of optical center O of the matrix 100 each has a same value of shift between the pixel 102 and its associated micro-lens 104, the shift being aligned with an axis passing by the optical center O of the matrix 100 and the pixel 102, or, said otherwise, with a radius passing by the pixel, preferably by the center O1 of the pixel 102.

For example, all the pixels 102 which are at a same distance d1 from the optical center O of the matrix 100, or, said otherwise, all the pixels 102 which are on a circle 106 centered on the optical center O, each has a same value sv1 of shift between the pixel 102 and its associated micro-lens 104 along an axis passing by the optical center O and by the pixel 102, preferably, by the center O1 of the pixel 102. Similarly, for example, all the pixels 102 which are at a same distance d2 from the optical center O of the matrix 100, or, said otherwise, all the pixels 102 which are on a circle 108 centered on the optical center O, each has a same value sv2 of shift between the pixel 102 and its associated micro-lens 104 along an axis passing by the optical center O and by the pixel 102, preferably, by the center O1 of the pixel 102.

For example, FIG. 1 shown, in a bottom left part of the Figure, a pixel 102 and its associated micro-lens 104 when the pixel 102 is arranged on the circle 106 and on an axis A passing by the pixel 102 and the optical center O of the matrix 100. Thus, the value of the shift between this pixel and its associated micro-lens is equal to sv1, this shift being aligned with the axis A.

Similarly, FIG. 1 also shown, in a bottom right part of the Figure, a pixel 102 and its associated micro-lens 104 when the pixel 102 is arranged on the circle 106 and on an axis A passing by the pixel 102 and the optical center O of the matrix 100. Thus, as for the pixel 102 on the circle 106 and the axis A, the value of the shift between the pixel 102 on the circle 106 and the axis B and its associated micro-lens is also equal to sv1, but is aligned with the axis B.

FIG. 1 shown, in a top left part of the Figure, a pixel 102 and its associated micro-lens 104 when the pixel 102 is arranged on the circle 108 and on the axis A passing by this pixel 102 and the optical center O of the matrix 100. Thus, the value of the shift between this pixel and its associated micro-lens is equal to sv2 and is aligned with the axis A.

However, as previously indicated, this circular shift is not sufficient anymore in view of the shrinking of the pixels and of the pixels having asymmetric shapes.

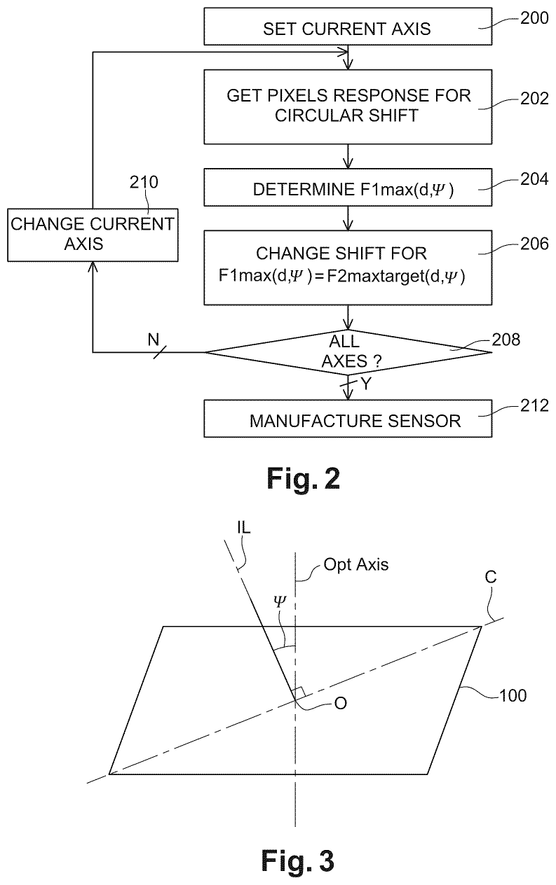

FIG. 2 illustrates, by a flow chart, an embodiment of a method for manufacturing a light sensor. In particular, the method aims to manufacture a sensor comprising a matrix 100 of pixels 102 each associated with a corresponding micro-lens 104, the micro-lens 104 being shifted with respect to the pixel 102 along an axis passing by the optical center of the matrix 100.

At a step 200 (block “SET CURRENT AXIS” in FIG. 2), a sensor similar to the one of FIG. 1 is used. This sensor, called reference sensor, is similar to the sensor to be manufactured is that the two sensors have the same matrix of pixels 102. Further, the reference sensor exhibits a circular shift between its pixels 102 and the corresponding micro-lenses. At step 200, the referenced sensor is considered without the lens module the sensor is configured to be mounted with.

A plurality of axes of interest are defined in the reference sensor, in the plane of the matrix 100. Each of the axes passes by the optical center O of the matrix 100.

According to one embodiment, the orientation of each of at least two axes among the plurality of axes, preferably of each axis of the plurality of axes, is defined by the shape of the pixels 102 and by the orientation of the pixels 102 in the matrix 100. For example, if, in the matrix 100, the pixels 102 have each a photosensitive area which is more elongated in a direction than in another one, a first axis of interest may be parallel with this direction, and, for example, a second axis of interest may be perpendicular to the first axis.

According to an alternative embodiment, the orientation of each axis of the plurality of axis may be determined arbitrarily, preferably with at least one couple of two perpendicular axes in the plurality of axes.

Still at step 200, a first axis in the plurality of axes of interest is set as the current axis.

Step 200 is followed by three successive steps 202 (block “GET PIXELS RESPONSE FOR CIRCULAR SHIFT” in FIGS. 2) and 204 (block “DETERMINE F1max (d, ψ)” in FIGS. 2) and 206 (block “CHANGE SHIFT FOR F1max (d, ψ)=F2maxtarget (d, ψ)” in FIG. 2).

These steps 202, 204 and 206 will be implemented for each of the axes of interest, for example in a sequential manner as illustrated in FIG. 2, or, in an alternative example not illustrated, in a parallel manner.

At step 202, for the current axis of interest, for example an axis of interest C, for a given figure of merit of the pixels 102, a response of each pixel 102 arranged on this current axis is obtained for each of a plurality of value of the chief ray angle, or, said otherwise, of the angle of the incident light on the matrix. These response for the given figure of merit is obtained with the reference sensor, by simulation and/or by measurement on a physical exemplary of the reference sensor.

For example, the figure of merit is the quantum efficiency of the pixels 102. More generally, the figure of merit is chosen in the groups comprising the quantum efficiency of the pixels 102, the relative illumination of the pixels 102, a modulation transfer function, the parasitic light sensitivity of the pixel. Said in other words, the figure of merit is chosen among a plurality of figures of merit of the pixels, the figures of merit each having an angular dependency, or, said otherwise, being dependent of the angle of incidence of the light on the pixels 102.

FIG. 3 illustrates the step 202 of FIG. 2. FIG. 3 shows the matrix 100 of pixels 102 of the reference light sensor, the pixels 102 being not represented in order to not overload the Figure.

At this step, the current axis of interest is, for example, the axis C. The axis C is, in the example of FIG. 3, a diagonal axis of the matrix 100.

With a characterization bench using a physical implementation of the reference sensor, or by simulation using a simulated reference sensor, the response of the pixels 102 arranged on the axis C to each of a plurality of incident light angles ψ are obtained. To do this, the incident light IL is projected on the matrix 100 with at least one ray comprised in a plane comprising the axis C and the optical axis OptAxis of the reference sensor. The optical axis OptAxis passes by the optical center O of the matrix 100 and is perpendicular to the plane of the matrix 100, or, said otherwise, to a plane defined by the directions X and Y.

In step 202, as the sensor is not yet mounted with the lens module, all the rays of the incident light IL are parallel to each other and are each comprised in a plane parallel to the plane comprising the axis C and the axis OptAxis. Thus, for each pixel 102 on the axis C, the incident light IL reaches the associated micro-lens (not 104 represented in FIG. 3) with an incident light angle v. By applying a rotation of the matrix 100 around an axis passing by the optical center O of the matrix 100 and being perpendicular to both axes C and OptAxis, the value of the angle ψ is modified.

Referring back to FIG. 2, after the step 202, the step 204 is implemented.

At step 204, a function F1max (d, ψ) is determined or interpolated. The function F1max (d, ψ) maximizes the responses of the pixels 102 on the current axis of interest, C in the present example. Said in other words, the function F1max (d, ψ) provides, for each distance d between the optical center of the matrix and a pixel 102 on the current axis of interest C, the value ψmax of the light incident angle ψ for which the pixel 102 has the best response value among the response values obtained by measurement or simulation at step 202. For example, when the figure of merit is the quantum efficiency, the best response value among a plurality of response values is the maximal one, whereas, when the figure of merit is the parasitic light sensitivity, the best response value among a plurality of response values is the minimal one. Thus, the function F1max (d, ψ) maximizing the responses of the pixels 102 on the current axis of interest could be either the function providing, for each distance d, the value max for which the response value of the pixel is maximal, or the function providing, for each distance d, the value ψmax for which the response value of the pixel is minimal, depending on the chosen figure of merit.

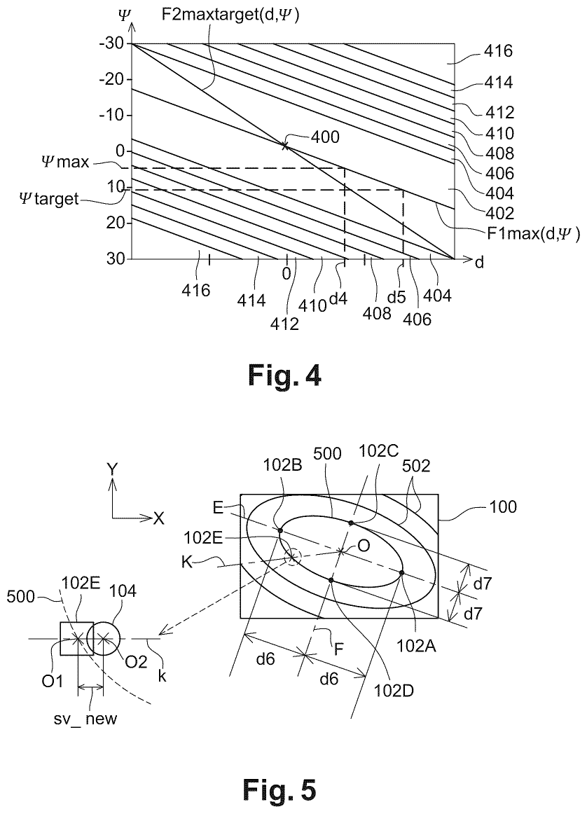

FIG. 4 illustrates an embodiment of steps 204 and 206 of the method of FIG. 2.

More particularly, the FIG. 4 shows response values obtained at step 202 for the chosen figure of merit, for each pixel 102 in the axis of interest, the axis C in this example, in function of the value of incident light angle ψ and of the distance d between the pixel 102 and the optical center O of the matrix. In FIG. 4, the distance d is represented on the abscissa axis and the value of the angle ψ is represented on the ordinate axis. In the present example, at step 202, the plurality of values of the angle ψ belong to the range from −30° to 30°. Further, the distance d has a null value for the pixel 102 arranged at the optical center O of the matrix 100, and takes increasing positives values on the current axis of interest C while moving away from the optical center O in a first direction, and increasing, in absolute value, negatives values on the current axis of interest C while moving away from the optical center O in a second direction opposite to the first one.

In the example of FIG. 4, the response values of the pixels 102 on the current axis of interest are normalized by the response value of the pixel 102 arranged at the optical center O of the matrix 100, the response of this pixel 102 being represented by a cross 400 in FIG. 4.

In the example of FIG. 4, the chosen figure of merit is such that the best response value for a given pixel is the maximal response value. However, those skilled in the art are capable of adapting the description made for this example to a case where the chosen figure of merit is such that the best response value for a given pixel is the minimal response value.

In the example of FIG. 4, several areas 402, 404, 406, 408, 410, 412, 414, 416 are represented. Each area corresponds to a range of normalized responses value having, for example, a width equal to 0.1. For example, area 402 corresponds to the range from 1 to 0.9, area 404 corresponds to the range from 0.9 to 0.8, area 406 corresponds to the range from 0.8 to 0.7, area 408 corresponds to the range from 0.7 to 0.6, area 410 corresponds to the range from 0.6 to 0.5, area 412 corresponds to the range from 0.5 to 0.4, area 414 corresponds to the range from 0.4 to 0.3, and area 416 corresponds to the range from 0.3 to 0. The representation of these area 402 to 416 is just for illustrative purpose and is not mandatory to implement the method of FIG. 2.

Further, FIG. 4 shows the function F1max (d, ψ). As previously indicated, the function F1max (d, ψ) gives, for each pixel 102 on the current axis of interest, the axis C in the example, the value ψmax of the angle ψ which corresponds, for the distance d of this pixel 102 from the optical center O, to the best response value of the pixel.

For example, in FIG. 4, for a pixel 102 arranged on the axis C at a distance d4 from the optical center O, the response value of the pixel 102 obtained at step 202 is the best (maximal in this example) for an angle ψ having a value ψmax equal to 5°.

Referring back to FIG. 2, after the step 204, the step 206 is implemented.

At step 206, a target function F2maxtarget (d, ψ) is determined or interpolated. The function F2maxtarget (d, ψ) maximizes a target response of the pixels 102 on the current axis of interest, C in the present example, for the chosen figure of merit. Said in other words, the function F2maxtarget (d, ψ) provides, for each distance d between the optical center of the matrix and a pixel 102 on the current axis of interest C, the value ψtarget of the light incident angle ψ for which it is desirable, or targeted, that the pixel 102 has the best response value for the chosen figure of merit.

This function F2maxtarget (d, ψ) is, for example, represented on FIG. 4. For example, in FIG. 4, for the pixel 102 at the distance d4 from the optical center of the matrix 100, it is targeted that the pixel 102 has a best response value for a value ψtarget of the angle ψ, ψtarget being equal to 11° in the example of FIG. 4 for this pixel 102. Although in the example of FIG. 4 the function F2maxtarget (d, ψ) is approximatively a linear function, the function F2maxtarget (d, ψ) is not limited to linear function, and, in other examples not represented, the function F2maxtarget (d, ψ) could be a polynomial function.

The function F2maxtaget (d, ψ) is defined by the designer of the sensor to be manufactured. For example, the function F2maxtarget (d, ψ) is determined based on the chief ray angle function of a lens module which will be assembled on the manufactured sensor. For example, the function F2maxtarget (d, ψ) is determined based in the chief ray angle function of the lens module so that the response value of each pixel 102 on the current axis of interest is maximized (or is the best) when the lens module is assembled with the manufactured sensor and the value chief ray angle of the light focused by the lens module on the matrix corresponds to a focusing on this pixel.

FIG. 7 illustrate, by a curve 700, the chief ray angle function, or CRA function, of an example of a lens module.

More particularly, the curve 700 shows for each distance d on the axis of interest, the evolution of the value of the chief ray angle v which provides a focusing light focused on this axis, at the distance d. In the example of FIG. 7, the lens of the lens module is considered to be centered on the optical axis OptAxis of the sensor, and is considered as being symmetrical by rotation around this axis OptAxis. Thus, only positive distances d from the optical center 0 are represented, the value of the chief ray angle for negative distances d being easily derivated by symmetry from curve 700.

For example, for a pixel 102 at a distance d4 on the axis of interest C, in the example of FIG. 7, the light focused by the lens module on the matrix 100 is focused on the axis C at the distance d4 if the chief ray angle ψ has a value ψ4 equal to 11°, which in fact corresponds to the value ψtarget shown, as an example, in FIG. 4.

Referring back to FIG. 2, at step 206, based on the function F1max (d, ψ) and F2maxtarget (d, ψ), for each pixel 102 on the current axis of interest, the axis C in this example, the value of the shift for the pixel 102 is modified in order to bring function F1max (d, ψ) closer, preferably equal, to function F2maxtarget (d, ψ). Said otherwise, for this pixel 102, a new value of the shift of its associated micro-lens with respect to the pixel, along the current axis of interest, is determine so that, for this value of shift, the function F1max is bring closer, equal, preferably to function F2maxtarget (d, ψ).

For example, in FIG. 4, for the pixel 102 at the distance d4 on the current axis of interest C, the pixel 102 belongs to, or verifies, the function F2maxtarget (d, ψ) if the value of the chief ray angle ψ is equal to ψtarget. However, the pixel 102 on the axis C which belongs to, or verifies, the function F1max (d, ψ) for the value ψtarget is at a distance d5. The value of the shift for the pixel 102 at the distance d5 on the axis C for the circular shift is known. In the manufactured sensor, for the pixel 102 at the distance d4 on the axis C, in order to have, for the value ψtarget of the chief ray angle, the best response for the chosen figure of merit, the value of the shift between its associated micro-lens and the pixel should be equal to the value of the shift between the pixel 102 at the distance d5 and its associated micro-lens for a circular shift. Thus, in the manufactured sensor, the value of the shift between the pixel 102 at the distance d4 on the axis C and its associated micro-lens is determined by the value of the shift between the pixel 102 at the distance d5 on the axis C for a circular shift.

For example, said in other word, at step 206, for each pixel on the axis of interest C, the value ψtarget of the light incidence angle for which the pixel 102 verifies the function F2maxtarget (d, ψ) is selected, this pixel being arranged at a first distance from the center O on the axis C (for example d4 for the pixel 102 used as an example in FIG. 4). Then, a second distance d on the axis C which corresponds to another pixel 102 verifying the function F1max (d, ψ) for the selected value ψtarget is determined (for example the distance d5 in the example of FIG. 4). Finally, the value of the associated micro-lens shift for the pixel 102 arranged at the first distance on the axis C (d4 for the pixel 102 used as example in FIG. 4) is determined by, for example is equal to or approximatively equal to, the value of the micro-lens shift of the pixel 102 arranged at the second distance on the axis C in the reference sensor (for example the distance d5 in the example of FIG. 4), or, said otherwise, with a circular shift.

Referring back to FIG. 2, as previously indicated, the steps 202, 204 and 206 are implemented for each axis of the plurality of axes of interest.

Thus, as for example illustrated in FIG. 2, step 206 implemented for a current axis of interest is followed by a step 208 (block “ALL AXES?” in FIG. 2). At step 208, it is verified whether the steps 202 to 206 have been implemented for each of the axes of interest.

If it is not the case (output N of the block 208), the current axis among the plurality of axes of interest is changed at a next step 210 (block “CHANGE CURRENT AXIS” in FIG. 2) and the step 210 is followed by step 202.

If it is the case (output N of the block 208), at a next step 212 (block “MANUFACTURE SENSOR” in FIG. 2).

At step 212, the sensor to be manufactured is effectively manufactured using, for pixel on each axis of interest, the value of the micro-lens shift with respect to the pixel equal to the value determined at step 206 for this pixel.

The above described gives new value of micro-lens shift for each pixel 102 on each axis of interest.

According to one embodiment, in order to also get new micro-lens shift values for the pixels 102 of the matrix which do not belong to the axes of interest, step 212 is implemented as follows.

A plurality of isometric lines of the values of micro-lens shift are interpolated or determined, for example in the plane XY of the matrix 100. The isometric lines are concentric with the optical center O of the matrix. Preferably, each isometric line has a shape identical the shape of the other isometric lines. Each isometric line passes by each pixel 102 of each axis of the plurality of axes interest which has a value, for example an absolute value, of micro-lens shift for the manufacturing equal to the micro-lens shift value corresponding to this isometric line.

FIG. 5 illustrates this implementation of the step 212, for an example where the axes of interest are two axes E and F perpendicular to each other.

For example, after the step 206 has been implemented for each of the axes of interest, in the example of FIG. 5, it has been determined that:
the new value of the micro-lens shift for a first pixel 102 (referenced 102A in FIG. 5) arranged on a first axis of interest, for example E, at a distance d6 from the center O is equal to sv_new along this first axis E,
the new value of the micro-lens shift is equal to sv_new along the first axis E for a second pixel 102 (referenced 102B in FIG. 5) arranged on the first axis of interest E at a distance d6 from the center O but on an opposite side of the axis with respect to the center O compare to the first pixel 102A, or said otherwise at a distance-d6 from the center,
the new value of the micro-lens shift for a third pixel 102 (referenced 102C in FIG. 5) arranged on an second axis of interest, for example F, at a distance d7 from the center O is equal to sv_new along this second axis F, and
the new value of the micro-lens shift is equal to sv_new along the second axis F for a fourth pixel 102 (referenced 102D in FIG. 5) arranged on the second axis of interest F at a distance d7 from the center O but on an opposite side of the axis with respect to the center O compare to the third pixel 102C, or said otherwise at a distance-d7 from the center.

Thus, there is an interpolated isometric line 500 corresponding to the value sv_new of micro-lens shift which passes by all the pixels 102A, 102B, 102C and 102D.

The other isometric lines 502 shown on FIG. 5 are for example interpolated similarly to the isometric line 500, or, in an alternative example, may be obtained by dilation operation of the isometric line 500 with respect to the optical center O of the matrix 100.

According to one embodiment, as shown in the example of FIG. 5, when the plurality of axes of interest comprises only two axes perpendicular to each other, the shape of the isometric lines is an elliptical shape having these two axes of interest as main axes of the ellipse.

According to alternative embodiment, when the plurality of axes of interest comprises only two axes perpendicular to each other, the shape of the isometric lines may be different from an elliptical shape.

Although in the example of FIG. 5, the plurality of axes of interest used when implementing the method of FIG. 2 only comprises two axes perpendicular to each other, in other examples not illustrated, these two axes may be not perpendicular to each other.

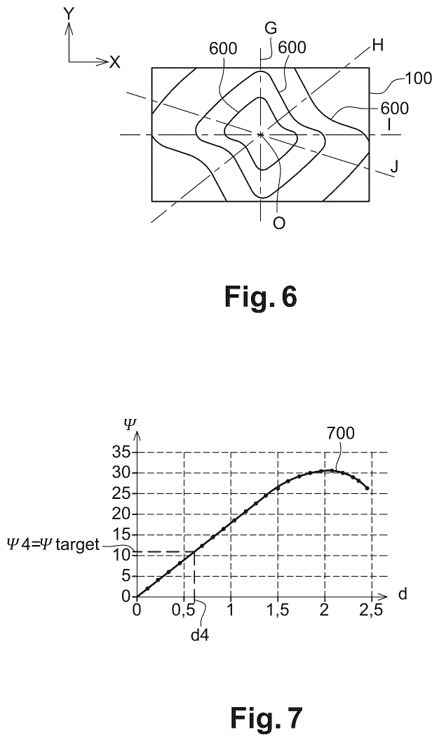

Further, although in the example of FIG. 5, the plurality of axes of interest used when implementing the method of FIG. 2 only comprises two axes, in other examples, the number of axes of interest when implementing the method of FIG. 2 may be superior to two, for example equal to 4 as illustrated by FIG. 6 in which the plurality of axes of interest used when implementing the method of FIG. 2 comprises exactly four axes G, H, I and J. In FIG. 6, the isometric lines of micro-lens shift values are referenced 600.

Still at step 212, based on the isometric lines determined or interpolated, when manufacturing the sensor, for each pixel 102 of the matrix 100 of the manufactured sensor, the value of the shift between this pixel and its associated micro-lens along an axis passing by the optical center O of the matrix 100 and by this pixel is determined by, for example is equal or approximatively equal to, the value of micro-lens shift of the isometric line passing by this pixel.

For example, in FIG. 5, an exemplary pixel 102 referenced 102E in FIG. 5 is arranged on the isometric line 500 corresponding to the micro-lens shift value sv_new. As shown on the bottom left part of FIG. 5 with a larger scale, the shift between this pixel 102E, preferably the center O1 of the pixel 102E, and its associated micro-lens 104, preferably the center O2 of the micro-lens 104, along the axis K passing by the optical center O and the pixel 102E is equal to the value sv_new of the isometric line 500 passing by the pixel 102E, for example by the center O1 of the pixel 102E.

According to one embodiment, the manufactured sensor obtained at the end of the implementation of the method of FIG. 2 comprises a matrix 100 of pixel 102 each associated with its corresponding micro-lens 104. For each axis of a plurality of axes, which, in practice, for example corresponds to the plurality of axes of interest defined in the method of FIG. 2, the value of the micro-lens shift along this axis for each pixel 102 disposed on this axis is determined by the distance of the pixel 102 from the optical center O of the matrix and is different between at least two axes of the plurality of axes for a same distance from the center, preferably is different between all the axes of the plurality of axes for a same distance from the center.

In the above description, according to one embodiment, each pixel 102 and its associated micro-lens 104 may correspond to respectively a group of at least two sub-pixels, preferably a group of N*N sub-pixels with N being an integer superior or equal to two, and a group of at least two sub-micro-lenses, preferably a group of N*N sub-micro-lenses. Then, for each pixel 102, each sub-pixel is associated with a corresponding one of the at least two sub-micro-lenses of the micro-lens 104 associated to this pixel 102, and reciprocally. In this case, when indicating that the micro-lens of the pixel is shifted with respect to the center of the pixel by a shift value along an axis passing by the pixel and the optical center of the matrix, this means that, for each sub-pixel of the pixel, the associated sub-micro-lens is shifted by said shift value with respect to the center of the sub-pixel, in a direction parallel to said axis.

Various embodiments and variants have been described. Those skilled in the art will understand that certain features of these embodiments can be combined and other variants will readily occur to those skilled in the art.

Finally, the practical implementation of the embodiments and variants described herein is within the capabilities of f those skilled in the art based on the functional description provided hereinabove.

1. A method of manufacturing a light sensor comprising a matrix of pixels each associated to a micro-lens having a shift with respect to the pixel along an axis passing by an optical center of the matrix and the pixel, the method comprising:
1) in a case where, for each pixel, a first value of the shift is only determined by a distance of the pixel from the optical center of the matrix, obtaining by simulation or measurement, for each axis of a plurality of axes passing by the optical center of the matrix, for each pixel on the axis, and for each of a plurality of values of light incident angle on the matrix, a response value of the pixel for a chosen figure of merit;
2) from the response values, for each axis of the plurality of axes, determining a first function providing, for each distance between the optical center of the matrix and a pixel on the axis, the value of the light incident angle for which the pixel has a best response value;
3) for each axis of the plurality of axes, for each pixel on the axis, determining a second value of the shift for bringing closer the first function to a second function providing, for each distance between the optical center of the matrix and a pixel on the axis, a target value of the light incident angle for which the pixel has a best target response;
4) manufacturing the sensor with, for each axis of the plurality of axes, and for each pixel on the axis, the value of the shift between the pixel and the associated micro-lens along the axis equal to the second value of the shift determined for the pixel.

2. The method according to claim 1, wherein the figure of merit is chosen in the group comprising a quantum efficiency of the pixel, the relative illumination of the pixels, a modulation transfer function of the pixel and a parasitic light sensitivity of the pixel and, for example, figures of merit of the pixel each being dependent of the angle of incidence of the light on the pixel.

3. The method according to claim 1, wherein an orientation of each of at least two axes among the plurality of axes is determined by a shape of the pixels and an orientation of the pixels in the matrix.

4. The method according to claim 1, wherein step 4) comprises, for each axis of the plurality of axes and for each pixel on the axis:
selecting the value of the light incidence angle for which the pixel verifies the second function;
determining the distance from the optical center for which another pixel on the axis verifies the first function for the selected value of the light incidence angle, the second value of the shift determined for the pixel being equal to the first value of the shift of the another pixel.

5. The method according to claim 1, wherein the step 3) further comprises interpolating a plurality of isometric lines of the second values of the shift, the plurality of isometric lines being concentric with the optical center and each isometric line passing by each pixel of each axis of the plurality of axes having its second value of the shift equal to the second value of the shift of the isometric line.

6. The method according to claim 5, wherein in step 4), when manufacturing the sensor, for each pixel, the value of the shift between the pixel and the associated micro-lens along an axis passing by the optical center of the matrix and by the pixel is determined by, for example is equal to, the second value of the shift of the isometric line passing by the pixel.

7. The method according to claim 1, wherein the plurality of axes comprises exactly two axes perpendicular to each other.

8. The method according to claim 5, wherein the plurality of axes comprises exactly two axes perpendicular to each other, and wherein each isometric line of the plurality of isometric lines has an elliptical shape.

9. The method according to claim 1, wherein the sensor is configured to be assembled with a lens module, and, at step 3), the second function is determined by a chief ray angle function of the lens module.

10. A light sensor comprising a matrix of pixels each associated to a micro-lens having a shift with respect to the center of the pixel along an axis passing by the optical center of the matrix and by the pixel, wherein, for each of a plurality of axes passing by the center of the matrix, the value of the shift along this axis between a pixel disposed on the axis and its associated micro-lens is determined by the distance of the pixel from the optical center of the matrix and is different, for a same distance, between at least two axes of the plurality of axes.

11. The light sensor according to claim 10, wherein an orientation of each of at least two axes among the plurality of axes is determined by a shape and an orientation of the pixels.

12. The light sensor according to claim 10, wherein:
a plurality of isometric lines of the values of the shift are defined so that the isometric lines are concentric with the optical center and each isometric line passes by each pixel of each axis of the plurality of axes having a value of the shift between the pixel and its associated micro-lens which is equal to the value of the shift of the isometric line; and
the value of the shift between each pixel and its associated micro-lens along an axis passing by the optical center of the matrix and by the pixel is determined by, for example is equal to, the value of the shift of the isometric line passing by the pixel.

13. The light sensor according to claim 10, wherein the plurality of axes comprises exactly two axes.

14. The light sensor according to claim 12, wherein the plurality of axes comprises exactly two axes and each isometric line has an elliptical shape.
